(19) United States
(12) Patent Application Publication
(10) Pub. No.: US 2007/0041680 A1
(43) Pub. Date: Feb. 22, 2007

(54) Process for assembling passive and active components and corresponding integrated circuit

(75) Inventors: Jean-Christophe Giraudin, Bernin (FR); Michel Marty, Varces (FR)

Correspondence Address: JENKENS & GILCHRIST, PC, 1445 ROSS AVENUE, SUITE 3200, DALLAS, TX, 75202, US

(73) Assignee: STMicroelectronics S.A., Montrouge (FR)

(21) Appl. No.: 11/504,216

(22) Filed: Aug. 15, 2006

(30) Foreign Application Priority Data
Aug. 18, 2005 (FR) 05008601

(51) Int. Cl. G02B 6/12; H01L 23/52

(52) U.S. Cl. 385/14; 257/758

(57) ABSTRACT

An integrated circuit includes at least two subassemblies: a first subassembly of active components and a second subassembly of passive components. The second subassembly of passive components is bonded beneath the first subassembly of active components. Interconnects are formed which pass through the first subassembly of active components, and the interconnects extend from the first subassembly of active components to the second subassembly of passive components.

### PRIORITY CLAIM

The present application claims priority from French Application for Patent No. 05 08601 filed Aug. 18, 2005, the disclosure of which is hereby incorporated by reference.

### BACKGROUND OF THE INVENTION

1. Technical Field of the Invention

The present invention relates to integrated circuits, and more particularly to the assembly of additional high-performance components, especially passive components, with active components.

2. Description of Related Art

An integrated circuit generally comprises active electronic components, especially transistors or diodes, and passive electronic components, especially resistors, capacitors or inductors.

The techniques commonly used in the production of an integrated circuit for assembling such passive components with active components have a number of drawbacks associated with the technique employed.

In particular, one of these techniques comprises for example integrating, on the surface of the substrate, passive components at the same level as active components. Such an assembly has the drawback of using up to 30% of the active area of the substrate. Furthermore, this process does not prevent the presence of parasitic currents between the active components and the passive components, thus limiting the performance of the integrated circuit obtained. Such an assembly process is described in the following articles: S. Donnay et al., “Single-chip versus single-package radios,” 1999 International Conference on High Density Packaging and MCMs, and S. Norlyng, “An overview of integrated component technologies,” IMAPS-Int. Microelectron. & Packaging Soc., May-June 2003.

Another of these techniques comprises carrying out, in a single operation, the mounting and interconnection of a passive component on the substrate. Such components are turned over during this mounting operation and are soldered by means of connection contacts located on the surface of the substrate. These connection contacts are in particular in the form of metal balls or bumps. Thus, the number of passive components that may be mounted on the substrate is limited by the number of connection contacts produced. Such connection contacts also have the drawback of using a portion of the area of the substrate available for integrating the active components. Furthermore, this process requires each of the passive components to be individually mounted on the substrate, increasing the fabrication cost of an integrated circuit. This technique is also described in the articles mentioned above.

In view of the foregoing, there is a need in the art to produce an assembly of passive and active components using the least possible area of substrate available for integrating the active components and by individually mounting the fewest possible passive components, and to do so while minimizing the influence on the process for fabricating active components and on their method of operation.

### SUMMARY OF THE INVENTION

According to one aspect, the invention provides an integrated circuit comprising at least two subassemblies, a subassembly comprising active components and a subassembly comprising passive components, said subassembly comprising passive components being bonded beneath said subassembly comprising active components.

The subassembly comprising active components is bonded onto the subassembly comprising passive components by an adhesive. This bonding is carried out without turning the subassembly comprising passive components upside down.

Thus, an integrated circuit having active components whose characteristics are substantially unmodified by the integration of the passive components is obtained.

Furthermore, an integrated circuit is also obtained whose subassembly comprising passive components has no difficulty in being aligned with the subassembly comprising active components.

The term “active components” is understood within the context of the present invention to mean electronic components using the semiconductor properties of certain materials, such as for example MOS (Metal Oxide Semiconductor) transistors, bipolar transistors, field-effect transistors (MOSFET transistors) or diodes.

The term “passive components” is understood within the context of the present invention to mean electronic components such as, for example, resistors, capacitors or inductors.

According to one feature of the invention, the integrated circuit comprises two subassemblies mutually bonded via a layer comprising an oxide-based material.

This layer makes it possible inter alia to bond the subassembly comprising active components to the subassembly comprising passive components, especially by electrostatic force. This layer also exhibits greater etching selectivity relative to the semiconductor substrate on which the active components are found.

According to one embodiment, interconnects pass through the subassembly comprising active components in order to provide a satisfactory electrical link between the interconnection levels located above the subassembly comprising active components and the passive components of the integrated circuit. The ohmic contact obtained is especially satisfactory in the case of capacitors.

According to one feature of the invention, said interconnects connect passive components to interconnection levels placed above the subassembly comprising active components.

According to one advantageous embodiment, said interconnection levels may also be located between the subassembly comprising active components and the subassembly comprising passive components.

According to one embodiment, said interconnects extend from a subassembly comprising active components to a subassembly comprising passive components.

In this way, the active components and the passive components are brought close together, thereby preventing losses in the connection lines between the two subassemblies.

Advantageously, said interconnects are in isolating regions of the subassembly comprising active components, said isolating regions being devoid of active components so as to avoid a short circuit.

According to another aspect, the subject of the invention is a process for fabricating an integrated circuit, comprising:

producing a subassembly comprising passive components;

producing a subassembly comprising active components; and, subsequently,

bonding said subassembly comprising passive components beneath said subassembly comprising active components.

The process makes it possible for the process for fabricating the subassembly comprising passive components to avoid having an influence on the process for fabricating the subassembly comprising active components. Thus, the characteristics of the active components are substantially unmodified by the assembly of the passive components. Furthermore, the independence of the fabrication processes makes it possible to avoid incompatibility problems between the steps of the two processes. The process also makes it possible to avoid problems of incompatibility between the materials of the active components and of the passive components.

The process also makes it possible to use all of the surface of the substrate for producing the active components.

In addition, the process allows collective mounting of the subassembly comprising active components on the subassembly comprising passive components.

According to one feature of the invention, producing said subassembly comprising active components includes a depositing a material allowing said subassembly to be handled comprising active components during the bonding step, thereby making it possible to reduce the influence of the process on the characteristics of the active components.

Advantageously, producing said subassembly comprising active components includes removing a substrate from said subassembly.

Advantageously, after the removal of the substrate, bonding said subassembly comprising passive components is carried out beneath said subassembly comprising active components.

According to another feature of the invention, after bonding, producing interconnects is carried out so as to connect said subassembly comprising active components to said subassembly comprising passive components.

According to another method of implementation, after the removal of the substrate, producing interconnection levels is carried out between said subassembly comprising active components and said subassembly comprising passive components.

According to another method of implementation, after the removal of the substrate, conducting pads are added beneath active components of said subassembly.

In accordance with an embodiment, a process comprises: forming passive integrated components supported by a first substrate, the passive integrated components being covered by a first insulating layer; forming active integrated components supported by in a second substrate, the active integrated components being separated from the second substrate by an second insulating layered; forming a third substrate above the active integrated components; removing the second substrate; and bonding the first and second insulating layers together.

In accordance with an embodiment, a process comprises: forming passive integrated components supported by a first substrate, the passive integrated components being covered by a first insulating layer; forming a plurality of interconnect layers including first and last layers, a first layer being adjacent the first insulating layer; forming active integrated components supported by in a second substrate, the active integrated components being separated from the second substrate by an second insulating layered; forming a third substrate above the active integrated components; removing the second substrate; and mounting the second insulating layer to the last layer of the plurality of interconnect layers.

### BRIEF DESCRIPTION OF THE DRAWINGS

A more complete understanding of the method and apparatus of the present invention may be acquired by reference to the following Detailed Description when taken in conjunction with the accompanying Drawings wherein:

FIG. 1 illustrates schematically a subassembly of an integrated circuit comprising a three-dimensional capacitor in a substrate;

FIG. 2 schematically illustrates a subassembly of an integrated circuit comprising active components on a substrate;

FIGS. 3-7 illustrate schematically the successive steps of a method of assembling the subassembly comprising active components and of the subassembly comprising a capacitor;

FIG. 8 illustrates a second method of assembling a subassembly comprising active components and a subassembly comprising a capacitor; and

FIG. 9 illustrates a third method of assembling a subassembly comprising active components and a subassembly comprising a capacitor.

### DETAILED DESCRIPTION OF THE DRAWINGS

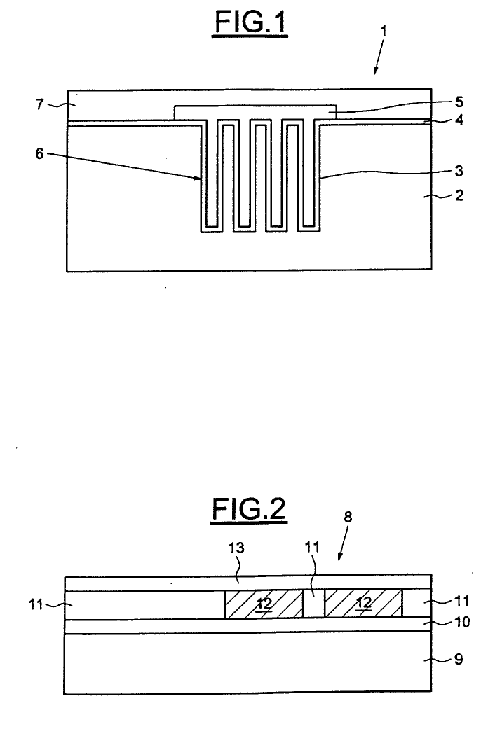

FIG. 1 shows a subassembly 1 of an integrated circuit comprising a substrate 2, which may be silicon or silicon on buried oxide (SOI), in which trenches 3 have been cut out beforehand, for example by chemical etching or plasma etching. The depth of the trenches 3 is for example of the order of 100 μm. A layer of dielectric material 4, which may for example be tantalum oxide (Ta₂O₅), silicon nitrite (SiN), silicon oxide (SiO2), alumina (Al₂O₃), hafnium oxide (HfO₂) or any other dielectric material of high permittivity, has then been deposited on the substrate 2, thus covering the sidewalls and the bottom of the cut trenches 3. The dielectric layer 4 may be deposited for example by a process of the ALD (Atomic Layer Deposition), LPCVD (Low-Pressure Chemical Vapor Deposition), PECVD (Plasma-Enhanced Chemical Vapor Deposition) or chemical type, or a combination of these techniques. A layer of metal 5, for example tungsten, has then been deposited on the substrate 2 by CVD (Chemical Vapor Deposition), or doped polycrystalline silicon deposited by LPCVD, so as to cover the dielectric layer 4 and to fill in the cut trenches 3. The layer of metal 5 on the surface of the dielectric layer 4 may subsequently undergo a chemical-mechanical polishing step. The ends of the layer 5 have then been removed by photolithography then by etching so as to expose the ends of the dielectric layer 4 of the subassembly 1. In a variant, the dielectric layer 4 may also be etched at the same time as the metal layer 5. Thus, a three-dimensional capacitor 6 obtained from a succession of electrodes that are formed from the metal layer 5 and are spaced apart by the dielectric layer 4 is obtained.

An insulating oxide layer 7 has then been deposited over the entire substrate 2 so as to cover the ends of the dielectric layer 4 and the metal layer 5. The oxide layer 7 has for example a thickness of greater 1 μm and is deposited conventionally in a manner known per se. The thickness of the oxide layer 7 must be large enough so as to ensure, after a chemical-mechanical polishing step, a planar surface.

The subassembly 1 may of course comprise several types of passive components and especially inductors or resistors, these not being shown in FIG. 1 for the sake of convenience.

FIG. 2 shows schematically a subassembly 8 of an integrated circuit comprising a substrate 9, for example silicon on insulator (SOI), on which an insulating layer 10, preferably silicon oxide, has been deposited. The insulating layer 10 is itself covered by a layer comprising active components 11 spaced apart by isolating regions 12. The layer comprising active components 11 is also covered with an insulating layer 13, for example silicon oxide. In other words, the layer comprising active components 11 is sandwiched between two insulating layers 10 and 13. The insulating layer 13 preferably undergoes a chemical-mechanical polishing step.

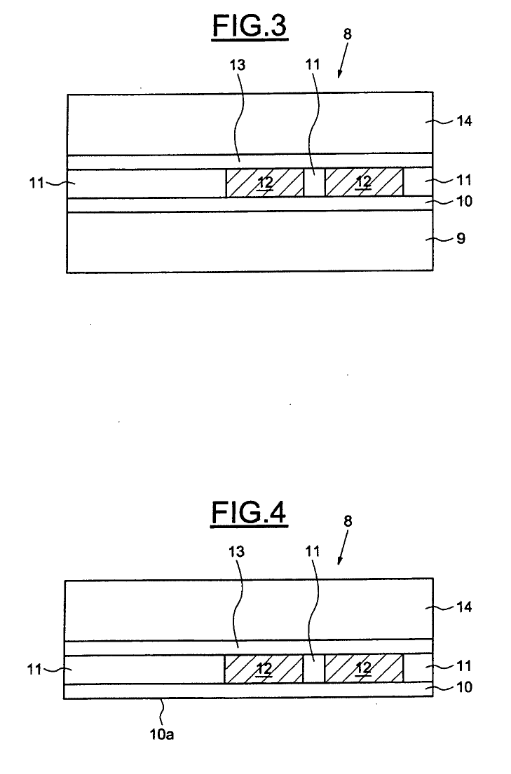

A material 14, which may be a rigid silicon substrate, is then bonded to the oxide layer 13 using a conventional low-temperature process known per se, such as that illustrated in FIG. 3. The rigid substrate 14 thus deposited makes it possible to handle the subassembly 8 so as to carry out the assembly.

The substrate 9 is then removed by a mechanical process known per se, then by a wet process as far as the lower surface 10a of the oxide layer 10, as shown in FIG. 4.

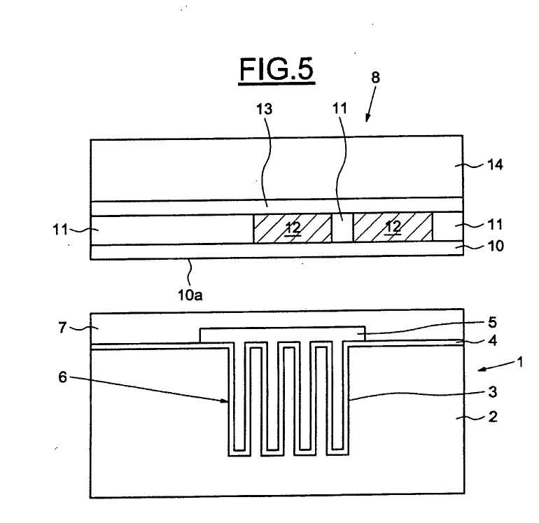

The subassembly 8 comprising active components 11 is then handled by means of the rigid substrate 14 so as to mount it on the subassembly 1 comprising the capacitor 6 as shown in FIG. 5. This mounting operation comprises bonding the subassembly 8 to the subassembly 1 by means of a low-temperature molecular bonding process. The rigid substrate 14 allows the subassembly 8 to be handled more easily, while minimizing the influence of the bonding step on the characteristics of the active components 11.

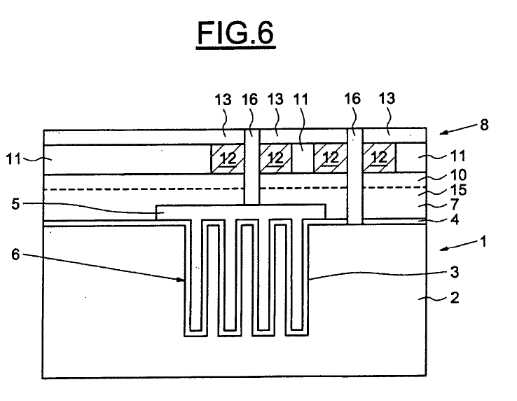

The rigid substrate 14 is then removed by a chemical process known per se, then by a wet process, as illustrated in FIG. 6.

As indicated in FIG. 6, the subassemblies 1 and 8 are mutually bonded together by means of a thick oxide layer 15. As may be seen in this figure, the layer 15 results from bonding the oxide layer 7 of the subassembly 1 comprising the capacitor 6 to the oxide layer 10 of the subassembly 8 comprising the active components 11. In other words, as shown by the dotted lines in FIG. 6, the oxide layer 15 results from bonding the layer 7 beneath the layer 10.

The use of an oxide layer, especially a silicon oxide (SiO₂) layer, prevents any debonding occurring during the step of bonding the two subassemblies. Furthermore, the oxide layer 15 prevents problems of incompatibility between the materials of the active components 11 and the materials of the capacitor 6. More particularly, the thickness of the oxide layer 15 makes it possible to limit the parasitic electrical interactions between the active components 11 of the subassembly 8 and the passive components of the subassembly 1.

Vias 16 are then made in the isolating regions devoid of active components 11 by photolithography followed by dry etching through the insulating layers 13 and 15 and the isolating regions 12 so as to connect the capacitor 6 of the subassembly 1.

The vias 16 have then been filled with a material having a satisfactory electrical conductivity, such as for example metal deposits by PVD (Physical Vapor Deposition) or CVD (Chemical Vapor Deposition). A chemical-mechanical polishing step then allows the surface of the subassembly 8 to be exposed. Production of the vias 16 after the bonding step thus provides a good ohmic contact of low resistivity.

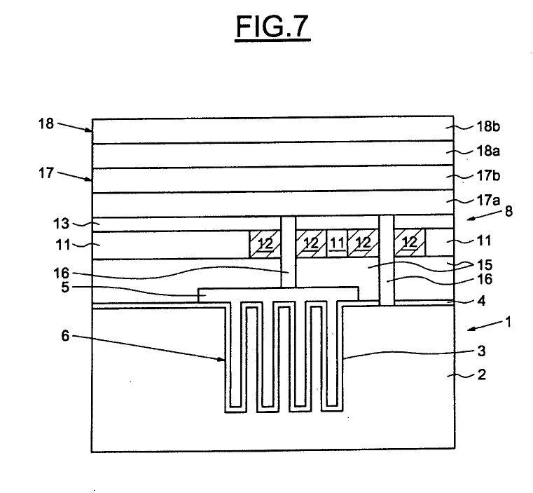

As illustrated in FIG. 7, interconnection levels 17 and 18 are then produced using conventional steps known to those skilled in the art. The interconnection levels 17 and 18 comprise metallization levels 17a and 18a and dielectric layers 17b and 18b.

Thus, the vias 16 pass through the subassembly 8 comprising active components 11 in order to ensure that there is a satisfactory electrical link between the interconnection levels 17 and 18 located above the subassembly 8 and the capacitor 6.

In another method of implementing the invention, an optional step may be added after the removal of the substrate 9 from the subassembly 8 as far as the lower surface 10a of the oxide layer 10, as shown in FIG. 4. This optional step comprises forming interconnection levels on the lower surface 10a of the oxide layer 10.

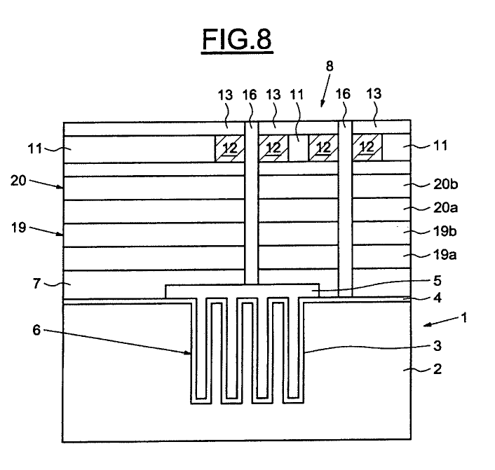

Thus, after the bonding step, interconnection levels 19 and 20 are located between the subassembly 8 comprising active components 11 and the subassembly 1 comprising the capacitor 6, as illustrated in FIG. 8. The interconnection levels 19 and 20 comprise metallization levels 19a and 20a and dielectric layers 19b and 20b, respectively.

Such a process allows a larger number of interconnects joining the subassembly 8 comprising active components 11 to the subassembly 1 comprising the capacitor 6 to be produced more easily, thus advantageously reducing problems of alignment between the two subassemblies.

Thus, in this method of implementation, the vias 16 also extend from the subassembly 8 comprising active components 10 to the subassembly 1 comprising the capacitor 6.

In another method of implementation, another optional step may be added after removal of the substrate 9 from the subassembly 8 as far as the lower surface 10a of the oxide layer 10 as shown in FIG. 4. This optional step comprises adding conducting contacts 21 beneath certain active components 10 of the subassembly 8.

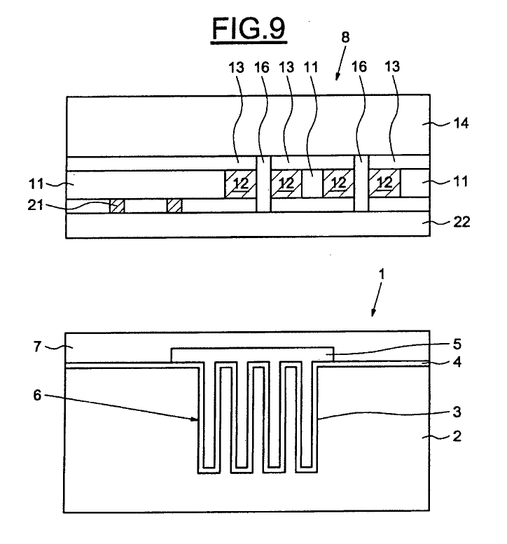

FIG. 9 shows, at the low-temperature bonding step, a subassembly 8 comprising active components 11 that are covered with an insulating oxide layer 13 and a subassembly 1 comprising the capacitor 6. The subassembly 8 is handled by means of the rigid substrate 14 so as to mount it on the subassembly 1 comprising the capacitor 6.

After removal of the substrate 9, conducting contacts 21 have been produced beneath certain active components 11 of the subassembly 8 through the oxide layer 10. The conducting contacts 21 are for example formed by etching the oxide layer 10 and then by filling by depositing metal.

An oxide layer 22 may then be deposited on the lower surface 10a of the insulating layer 10 before the two subassemblies 8 and 1 are assembled.

The conducting contacts 21 make it possible for the resistance of the silicon beneath the active components 11, for example the resistance of a collector of vertical bipolar transistors, to be locally reduced.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. An integrated circuit comprising:
a first integrated circuit subassembly including active components;
a second integrated circuit subassembly including passive components; and
interconnects which pass through the first subassembly of active components,
wherein said second subassembly is bonded beneath said first subassembly, and
wherein said interconnects extend from the first subassembly of active components to the second subassembly of passive components.

2. The integrated circuit according to claim 1, wherein the first and second subassemblies are mutually bonded via a layer comprising an oxide-based material.

3. The integrated circuit according to claim 1, wherein said interconnects connect passive components to interconnection levels placed above the first subassembly of active components.

4. The integrated circuit according to claim 1, further comprising interconnection levels which are located between the first subassembly of active components and the second subassembly of passive components.

5. The integrated circuit according to claim 4, wherein said interconnects pass through the interconnection levels.

6. The integrated circuit according to claim 1, wherein said interconnects are formed in isolating regions of the first subassembly of active components, said isolating regions being devoid of active components.

7. A process for fabricating an integrated circuit, comprising:
producing a first subassembly including passive components;
producing a second subassembly including active components;
subsequently bonding said first subassembly of passive components beneath said second subassembly of active components; and
after bonding, producing interconnects so as to connect said second subassembly of active components to said first subassembly of passive components.

8. The process according to claim 7, wherein producing said second subassembly of active components includes depositing a material allowing said second subassembly to be handled during bonding.

9. The process according to claim 8, wherein producing said second subassembly of active components includes removing a substrate from said second subassembly.

10. The process according to claim 9, wherein, after removal of the substrate, a bonding said first subassembly of passive components is carried out beneath said second subassembly of active components.

11. The process according to claim 9, further including, after the removal of the substrate, producing interconnection levels between said second subassembly of active components and said first subassembly of passive components.

12. The process according to claim 9, further including, after the removal of the substrate, adding conducting pads beneath active components of said second subassembly.

13. A process, comprising:
forming passive integrated components supported by a first substrate, the passive integrated components being covered by a first insulating layer;
forming active integrated components supported by in a second substrate, the active integrated components being separated from the second substrate by an second insulating layered;
forming a third substrate above the active integrated components;
removing the second substrate; and
bonding the first and second insulating layers together.

14. The process of claim 13 further comprising:
removing the third substrate; and
forming a plurality of interconnect layers above the active integrated components.

15. The process of claim 14 further comprising electrically interconnecting the interconnect layers, the active integrated components and the passive integrated components through vias.

16. The process of claim 13 further comprising forming a plurality of metal contacts for and below the active integrated components.

17. A process, comprising:
forming passive integrated components supported by a first substrate, the passive integrated components being covered by a first insulating layer;
forming a plurality of interconnect layers including first and last layers, a first layer being adjacent the first insulating layer;
forming active integrated components supported by in a second substrate, the active integrated components being separated from the second substrate by an second insulating layered;
forming a third substrate above the active integrated components;
removing the second substrate; and
mounting the second insulating layer to the last layer of the plurality of interconnect layers.
